(19) United States
(12) Patent Application Publication
(10) Pub. No.: US 2010/0307403 A1
(43) Pub. Date: Dec. 9, 2010

(54) (110) DISLOCATION-FREE MONOCRYSTALLINE SILICON AND ITS PREPARATION AND THE GRAPHITE HEAT SYSTEM USED

(75) Inventors: Haoping Shen, Tianjin (CN); Yutian Wang, Tianjin (CN); Yuanqing Hu, Tianjin (CN); Weize Shang, Tianjin (CN); Xiang Li, Tianjin (CN); Haijing Li, Tianjin (CN); Wei Si, Tianjin (CN); Runfei Gao, Tianjin (CN)

Correspondence Address: WANG & HO, 66 HILLTOP ROAD, MILLINGTON, NJ, 07946, US

(73) Assignee: Tianjin HuanOu Semiconductor Material and Technology Co., Ltd., Tianjin (CN)

(21) Appl. No.: 12/377,681

(22) PCT Filed: Apr. 19, 2007
(86) PCT No.: PCT/CN2007/001287

§ 371 Date: Feb. 17, 2009

(30) Foreign Application Priority Data
Dec. 6, 2006 (CN) 200610129891.6

(51) Int. Cl. C30B 15/22; C30B 15/14

(52) U.S. Cl. 117/15; 117/217

(57) ABSTRACT

The invention discloses (110) dislocation-free monocrystalline silicon and its preparation and the graphite heating system used. The process for preparation is as follows: clearing furnace and tidy the heat field; loading furnace; vacuumizing and argon charging; heating raw material; crystal seeding; expanding shoulder; rotating shoulder: speeding up the speed of shoulder-expanding; equal diameter: after shoulder-rotating, stabilize the crystal growth speed; finishing: turning off the power of crucible, decreasing the drawing rate manually; turning off the furnace. The graphite heating system includes: upper insulation column, lower insulation column and hearth tray arranged from the top down to form the external shell, and the peripheral surface is a stepped structure, and the thickness of the insulation layer of the upper insulation column is 20-30 mm, the thickness of the insulation layer of the lower insulation column is 60-70 mm, and the thickness of the insulation layer of the hearth tray is 70-80 mm. (110) dislocation-free monocrystalline silicon is cylinder structure, on its expanded shoulders 2 symmetrical main crest lines and 4 symmetrical sub-crest lines are formed, and 2 symmetrical main crest lines are formed on crystal cylinder surface. The present invention realizes manufacturing (110) dislocation-free monocrystalline silicon so as to meet the demand of the domestic and international markets.

### FILED OF THE INVENTION

The present invention relates to a pulling crystal technique, especially a (110) dislocation-free monocrystalline silicon suitable for special semiconductor and solar photoelectric devices and its preparation and the graphite heating system to be used.

### BACKGROUND OF THE INVENTION

It is well known, in silicon crystal lattice, since the angle between (110) crystal face and (111) crystal face is 90° and 35° 16′, dislocation on (111) crystal face with angle of 90° is the same as (110) lattice orientation. The production of (110) single crystal with traditional pulling technique, has dislocation limitation as well, thus, in order to produce (110) dislocation-free monocrystalline silicon, the dislocation should be eliminated but it is a technical problem in pulling technique all along.

Uses of improving drawing rate greatly, controlling diameter and length of crystal seed and, controlling shoulder-expanding speed, increasing the finish length of single crystal and controlling the diameter of single crystal in finish, are the key points to pulling (110) dislocation-free monocrystalline silicon successfully, while, technical conditions suitable for (110) dislocation-free monocrystalline silicon is nonnegligible.

(100), (110) and (111) are common crystal face for silicon single crystal, their growth temperature gradients needed are various, that is due to silicon single crystal faces with different lattice orientations have different spacing, so the growth speed of each crystal face in normal direction is different. Those crystal faces with large interplanar spacing have smaller affinity among atoms, so their growth are difficult; while those with small interplanar spacing have larger affinity among atoms, so their growth are easy and the growth speeds are faster.

Thus, the normal direction of (100) crystal face family is the fastest; (110) crystal face family takes the second; (111) crystal face family takes the slowest. It is similar in cauterization, the cauterizing speed of (100) crystal face family is the fastest; (110) crystal face family takes the second; (111) crystal face family takes the slowest. So the growth of single crystal with different lattice orientation needs different temperature gradient.

(111) needs the largest temperature gradient, (100) needs the smallest temperature gradient, while the growth of silicon single crystal of (110) lattice orientation is between (111) lattice orientation and (100) lattice orientation in respect to the requirement of heat field gradient.

Using the previous heating system for pulling (110) dislocation-free monocrystalline silicon almost has no effect on its crystal form, however, single crystal has fundamental limitations as below:

A, the previous heat field gradient is relatively small, the improvement of (110) single crystal growth speed will occur, single crystal shape is elliptical, (the degree of deviation of the crystal seeding lattice orientation also has some impacts) not beneficial to the post procedure of single crystal or even not forming crystal.

B, heat field gradient is relatively large, single crystal often break off its crest, and influence the effective length of non-dislocation single crystal.

C, since the dislocation of (110) lattice orientation single crystal has its own particularity, if heat field gradient is too large, the temperature difference between the foreside and backside of the single crystal is effectively widened, upon the dislocation occurs, under the impact of heat stress ,the dislocation could run through the whole single crystal.

In summary of the above, in order to achieve the heat field temperature gradient suitable for controlling (110) dislocation-free monocrystalline silicon, the thickness of the insulation layer of the upper insulation column, lower insulation column and hearth tray have to be redesigned.

### SUMMERY OF THE INVENTION

The invention aims to solve a technical problem, providing a (110) dislocation-free monocrystalline silicon suitable for special semiconductor and solar photoelectric devices and its preparation and the graphite heating system to be used.

The invention uses the following scheme: a (110) dislocation-free monocrystalline silicon and its preparation and the graphite heating system to be used, in which the process for producing (110) dislocation-free monocrystalline silicon includes the following steps:

(1) clean the furnace and tidy heat field: after charging argon into the hearth, cleaning the sub-furnace room, cleaning the graphite pieces and volatile in the hearth and the hearth;

(2) load the furnace: put the graphite pieces into the furnace in turn, and make the furnace column on its place, put multi-crystal material and alloy into a quartz crucible, allow the lower hole of the sub-room jointed with the upper hole of the furnace column, clean the seed crystal collet, set up (110) seed crystal, then seal the furnace ;

(3) vacuumize, charge argon: when the vacuum meets under the set value, charge argon;

(4) heat raw material: turn on the rotation outfit of the crucible, adjust its place and begin to heat;

(5) crystal seeding: the raw material is burned up completely, after the temperature of the melt in furnace is stable, bake the crystal and fuse the crystal seeding, pull the thin neck;

(6) expand shoulder: shoulder-expanding is carried out, monitor the diameter of the expanded shoulder;

(7) rotate shoulder: speeding up the speed of shoulder-expanding;

(8) equal diameter: after the shoulder rotation, stabilize the crystal growth speed;

(9) finish: turn off the power of the crucible, decrease the drawing rate manually for finishing;

(10) turn off the furnace: raise the crystal off the liquid surface, turn off the heating switch, crystal growth, crystal rotation, crucible rotation, crucible power, stopping charge of argon.

When cleaning furnace and tidying the heat field, charge argon until the hearth pressure the same as ambient atmosphere.

Said vacuumizing and charging argon is carried out under air pressure below 5 Pa, and the argon flow is at 50 L/min, furnace pressure indication is at 1300-1500 Pa.

During heating the material, adjust the crucible mark at +1090˜+1100 mm, the OP value of Eurotherm is added to 20, then the OP value is added by 25 every 15 min, that is slowly adding the power till the OP value is 100, when the raw material is all fallen down into the quartz crucible, the crucible mark is at 1015˜1025 mm.

During crystal seeding, the crystal seeding diameter should be ≧5 mm, obvious retractation and expansion are necessary, the ratio of retractation and expansion is higher than 100%, the drawing rate of crystal seeding should be ≧5 mm/min, the length of crystal seeding is 140˜300 mm.

Said expanding shoulder is to expand shoulder then gradually reducing the growth speed of crystal seeding to 0.5˜0.7 mm/min, during expanding shoulder, the speed is controlled at 0.2˜1.5 mm/min

Said shoulder rotation is to improve the drawing rate to 2.2 mm/min when the diameter is 150˜130 mm, the diameter of the shoulder is controlled at 150˜160 mm.

Said equal diameter step, the drawing rate of the single crystal head is 1.0˜3.0 mm/min, the drawing rate of the tail should be 0.5˜2.0 mm/min.

In said finishing step, the length of single crystal is larger than the diameter of the crystal, minimum diameter at finishing is ≦10 mm.

In which, the graphite heating system to produce (110) dislocation-free monocrystalline silicon includes an upper insulation column, a lower insulation column and a hearth tray arranged from the top down to form the external shell, and the peripheral surface of the upper insulation column, lower insulation column and hearth tray is a flat structure, a draft tube is set inside, a quartz crucible filled with silicon liquid and a graphite crucible covered outside, a graphite axis connected at bottom of the graphite crucible, a heater on the outside of the graphite crucible, the peripheral surface of said upper insulation column, lower insulation column and hearth tray is a stepped structure, and the thickness of the insulation layer of the upper insulation column is 20-30 mm, the thickness of the insulation layer of the lower insulation column is 60-70 mm, the thickness of the insulation layer of the hearth tray is 70-80 mm.

A (110) dislocation-free monocrystalline silicon, being cylinder structure, on the expanded shoulders of (110) dislocation-free monocrystalline silicon 2 symmetrical main crest lines and 4 sub-crest lines at the two sides of the 2 main crest lines are formed, on the crystal column surface of (110) dislocation-free monocrystalline silicon 2 symmetrical main crest lines extended from the expanded shoulders are formed.

The (110) dislocation-free monocrystalline silicon and its preparation and the graphite heating system to be used in the invention has a simple technical process, mostly in crystal seeding, shoulder-pulling, equal diameter and finishing in pulling technique, and the graphite heating system is simple in structure. The present invention realizes manufacturing (110) dislocation-free monocrystalline silicon so as to meet the demand of the domestic and international markets.

The various features of novelty which characterize the invention are pointed out with particularity in the claims annexed to and forming a part of this disclosure. For a better understanding of the invention, its operating advantages, and specific objects attained by its use, reference should be made to the drawings and the following description in which there are illustrated and described preferred embodiments of the invention.

### BRIEF DESCRIPTION OF THE DRAWINGS

FIG. 1 is the structural diagram for the graphite heating system in the invention;

FIG. 2 is the structural diagram of shoulder-expanding of (110) dislocation-free monocrystalline silicon;

FIG. 3 is the structural diagram of section plane of (110) dislocation-free monocrystalline silicon, where : 1: upper insulation column; 2: lower insulation column; 3: hearth tray; 4: draft tube; 5: silicone liquid; 6: graphite crucible; 7: graphite axis; 8: heater; 9: crystal seeding; 10: shoulder expanding; 11: main crest lines; 12: sub-crest lines; 13: crystal cylinder.

### DETAILED DESCRIPTION OF PARTICULAR EMBODIMENTS OF THE INVENTION

The (110) dislocation-free monocrystalline silicon and its preparation and the graphite heating system to be used in the invention (for example, 6 inch (110) dislocation-free monocrystalline silicon) are further illustrated by combining some preferred embodiments.

The process for producing (110) dislocation-free monocrystalline silicon of the invention, is to complete the preparation work at first, including: clean the room, wear the work clothes and gloves, cap and respirator. Turn on the main power of the single crystal furnace, start up the main power of the control screen, each indicator is indicative and able to work, particularly including the following steps:

(1) clean the furnace and tidy the heat field:

1) make sure the isolating valve is open, open the valve of the argon flowmeter, charge argon into the hearth, observe the pressure gauge on the left of the sub-furnace room. If the pressure inside the furnace is the same as ambient air pressure, i.e. the indicated value of the pressure gauge is zero, close the valve of the argon flowmeter, rotate the hydraulic pressure start-up button under the control cabinet from “stop” to “ready”, then press a red “uninstall” button. Then press the green “raise sub-room” button to raise the sub-room to the limiting position, press the green “raise furnace cover” button to raise the sub-room to the limiting position and push the sub-room away towards the left side, clean the sub-furnace room with a clean cloth;

2) take the graphite draft tube off, make sure the furnace column raise will not collide with the cover, press the “raise furnace column” to raise the column till higher than the graphite heat field, withdraw the guide bar, then pull it rightward;

3) the insulation layer thickness of the upper insulation column 1 is adjusted to 25 mm, the insulation layer thickness of the lower insulation column 2 is adjusted to 63 mm, the insulation layer thickness of the hearth tray 3 is adjusted to 75 mm. Then suck out volatile in the graphite pieces and hearth with dust collector, wipe the hearth with cloth.

(2) charge the furnace:

1) wear gloves, put the graphite pieces into the furnace in turn. Note whether the distance between the heater and the baffle-board is appropriate, whether the distance between the graphite crucible and heater is appropriate, make sure whether the light hole of the insulation barrel and that of the furnace column is in alignment;

2) make the furnace column on its place, note when rotating the column, do not touch the graphite pieces, allow the guide bar entering the guide groove of the furnace column, press the red “lower furnace column” button to lower the furnace column, note the bottom hole of the furnace column do not touch the graphite pieces;

3) wear gloves, check the quartz crucible's quality, if no cracks, collapse and fine grains, it can be put into the graphite crucible;

4) weigh the multi-crystal material and alloy to be used, wear gloves to put them into the quartz crucible, the bits at the bottom, the bulks in the middle, and the particles on the top and in spacing, touching the crucible wall as less as possible, loading the material carefully, not too crowded lest the crucible swelled to be cracked or split;

5) make sure it is OK after checking. Move the sub-furnace room directly over the furnace column, press the red “lower furnace cover” button to lower the sub-room, to make the lower hole jointed with the upper hole, clean the collet of the crystal seeding, load (110) crystal seeding, check whether the wire rope is intact, then slowly move the sub-room directly over the furnace cover, press the red “lower furnace cover” button, then make sure the flap valve is open.

(3) vacuumizing, charging argon:

1) checking whether the cooling water is opened, to keep the pressure at 0.8-2.0 KG/cm2;

2) starting up the main pump, open the valve of vacuum pipe of the main pump for vacuumizing;

3) when the vacuum is below 5 Pa, open the argon valve, control argon flow at 50 L/min, allowing the furnace pressure indicating 1300-1500 Pa.

(4) heat the raw material:

1) check the crystal growth, crystal rotation, crucible growth and whether the power is closed or at zero place;

2) start up crucible rotation outfit with 1 R/min. Press the red button on clutch (red light is on), press the “quickly raise crucible” or “quickly lower crucible” button on the control cabinet, allow the crucible mark at +1090˜+1100 mm;

3) check the water pressure gauge of circling cooling water, allowing the pressure at 0.08˜0.2 Mpa;

4) reset the OP value in the diameter-controlled parameters of computer to zero, then set the OP value as 800 or 1200.

5) fuse the raw material, press the green heating button on the electricity-controlled cabinet (green light is on), check“Eurotherm” is on manual (MAN) condition or not, and the OP is zero or not, press the red heating button on the electricity-controlled cabinet panel in the single crystal furnace to start up heating. The OP value of Eurotherm is added to 20, then the OP value is added by 25 every 15 min, that is slowly adding the power till the OP value is 100. The raw material is burnt completely in 4˜4.5 h. During burning the material, lower the crucible mark based on the practical situation, when the material is all fallen down into the quartz crucible, the crucible mark is at 1015˜1025 mm.

(5) crystal seeding:

1) crystal seeding preparation, adjust the crucible mark to 1100 mm after the raw material is burnt completely, increase the rotation speed to 1˜8 R/min. Lower the OP value to crystal seeding power of about 65, waiting the temperature of the melt in furnace to achieve stable state. The time duration should be controlled within 0.5 h. After the SP value is stable, press manual/auto on Eurotherm to switch the SP to auto. Open “crystal growth manual control box” crystal growth power and rotate the crystal growth potentiometer, indicating 1.00, open the crucible growth power and rotate the crucible growth potentiometer, indicating 0.1, this value is the set crucible growth ratio, then reset the crystal growth potentiometer to zero, turn off the crystal growth and crucible growth power. Turn on the crystal rotation and crystal growth power, adjust the rotation slowly to 12 R/min, and press “quickly lower crystal” button on “crystal growth manual control box”, lower crystal seeding to a distance of 10˜20 mm from the liquid surface for baking;

2) fusing crystal seeding, insert the crystal seeding into the melt for high temperature fusing, fuse off a part of each four side on the head of the square crystal seeding to form angels on the four crests, indicating the fuse is well done (adjust the temperature set point depending on the temperature);

3) pull the thin neck, adjust the crystal seeding journey to zero, rotate the crystal growth potentiometer, increase gradually the drawing rate of the crystal seeding ≧5 mm/min, keeping the diameter of the crystal seeding ≧5 mm, obvious retractation and expansion are necessary, the ratio whereof is higher than 100%, the drawing rate of crystal seeding should be ≧5 mm/min, the length of the crystal seeding should be higher than the requirement of (100) lattice orientation, the particular length is specified as 140˜300 mm, to avoid being fused off.

(6) shoulder-expanding:

Expand the should when the crystal seeding growth speed is gradually lowered down to 0.5˜0.7 mm/min, during the shoulder-expanding, control the shoulder-expanding speed at 0.2˜1.5 mm/min, increase or reduce the temperature setting point depending on shoulder-expanding speed, put the diameter gauge on the observation port and monitor the diameter of shoulder-expanding.

(7) shoulder-rotating:

When expanding shoulder till the diameter measured value as 30˜150 mm, increase the drawing rate to 2. 2 mm/min quickly, control the shoulder diameter measured value as 150˜160 mm.

(8) equal diameter:

When the aperture is closed, the shoulder rotation is finished, press the crucible growth power button on the control cabinet (green light is on), to follow crucible growth, crystal growth speed is reduced according to practical situation. At the same time, reset the length in computer as reference point in equal diameter self-control. Manually keeping a while, after the crystal growth speed is stable, adjust the IRCON nut on the left of the sub-room, and observe the aperture through an eyelet on it, to allow ⅓ of that pressed on the crystal. The d1 of the “diameter-controlled parameter” of the computer is about 400, then press the “diameter A/M” on the computer, the indicator light is on. Press the “temperature regulation A/M”, the indicator light is on, showing that the crystal-pulling is in self-controlled state. In the technique of equal diameter, the pulling speed of the head of the single crystal is 1.0-3.0 mm/min, and the pulling speed of the tail is 0.5-2.0 mm/min.

(9) finish:

When the material in the crucible is left 6kg, the temperature regulation and crystal growth are changed from auto to manual. Turn off the crucible growth power and lower the pulling speed a little manually, and continually adjust it by temperature regulation speed or Eurotherm in computer for finishing. The finishing length of the single crystal is larger than the diameter of the crystal, e.g. if the diameter of the crystal is 4 inch, the finishing length of the single crystal should be larger than 4 inch, minimum finishing diameter should be ≦10 mm.

(10) blow off:

Use “quickly raise crystal” to lift the crystal a distance of 30-50 mm from the liquid surface; reset the OP value to zero slowly, and turn off “heating” switch (the indicator light is off); turn the crucible rotation and crystal rotation potentiometer slowly to zero, and close the crystal growth, crystal rotation, crucible rotation, crucible growth powers; after one and an hour and a half, turn off the valve of the argon flowmeter, stop charging argon. Turn off the “main room pump” power switch on the control cabinet after the globe valve behind the boiler is turned off.

The single crystal boiler used in the invention is JRDL-800, CG6000 type single crystal boiler, pressure within the boiler: 1.3-1.6×103 Pa (15-20 Torr); heat system is Φ16-18″ graphite heat system; quartz crucible is Φ16-18″ quartz crucible, crucible growth ratio: 1.0: 0.128; crystal seeding type is P type (110); pressure-reduced air is high purity of argon; argon flow: 40-60 L/min.

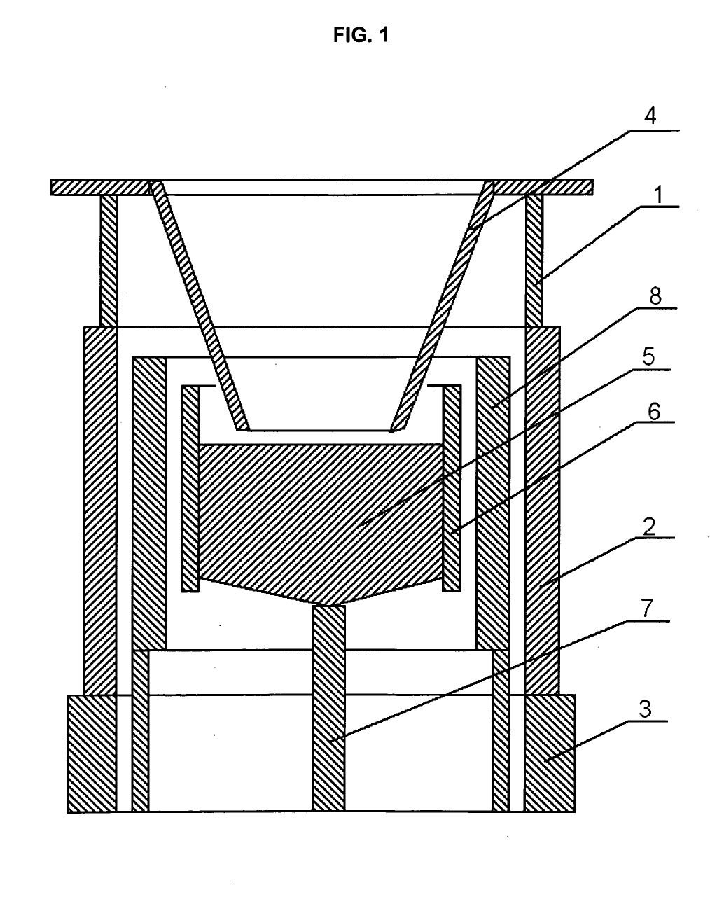

As in FIG.1, the graphite heat system for producing (110) dislocation-free monocrystalline silicon, including an upper insulation column 1, a lower insulation column 2 and a hearth tray 3 arranged from the top down to form the external shell, in which the internal peripheral surface of the upper insulation column, lower insulation column and hearth tray is a flat structure, a draft tube 4 is set inside, a quartz crucible filled with silicon liquid 5 and a graphite crucible 6 covered outside, a graphite axis 7 connected at bottom of the graphite crucible, a heater 8 on the outside of the graphite crucible. In order to adjust the temperature gradient of the graphite heat system, the external peripheral surface of said upper insulation column 1, lower insulation column 2 and hearth tray 3 is a stepped structure, and the insulation layer of the upper insulation column is thick of 20-30 mm, the insulation layer of the lower insulation column is thick of 60-70 mm, the insulation layer of the hearth tray is thick of 70-80 mm. In the embodiment: the insulation layer of the upper insulation column 1 is thick of 26 mm, the insulation layer of the lower insulation column 2 is thick of 64 mm, the insulation layer of the hearth tray 3 is thick of 78 mm, carbon felt (or hard felt) can be used as insulation material.

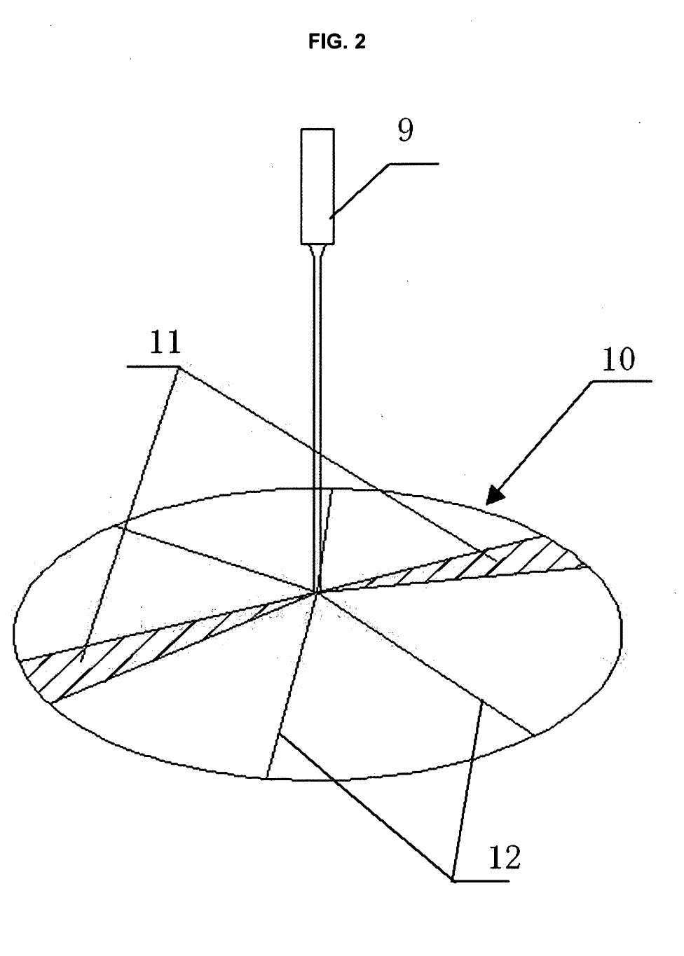

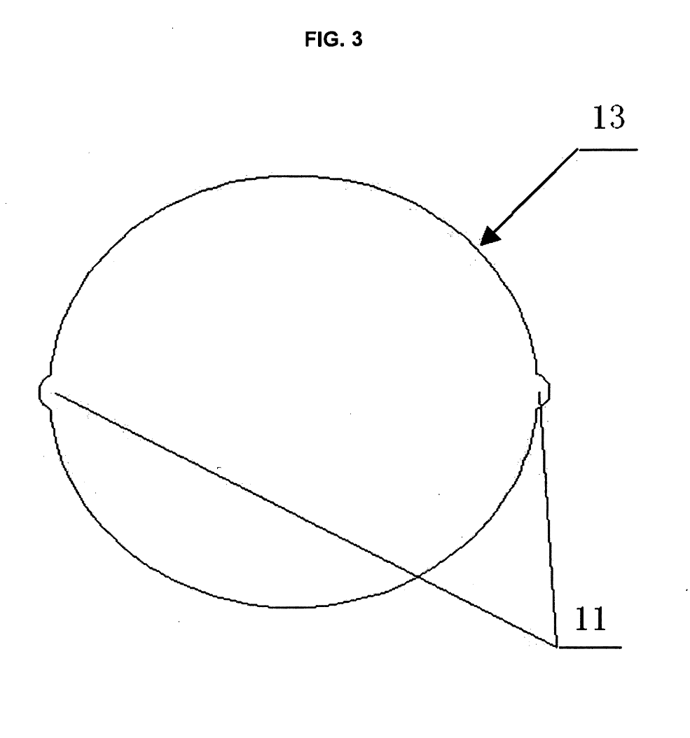

As FIG. 2 and FIG. 3, (110) dislocation-free monocrystalline silicon in the invention, being column structure, on its ends namely the expanded shoulders of (110) dislocation-free monocrystalline silicon 2 symmetrical main crest lines and 4 sub-crest lines at the two sides of the 2 main crest lines are formed, on the crystal column surface of (110) dislocation-free monocrystalline silicon 2 symmetrical main crest lines extended from the expanded shoulders are formed.

What is claim is:

1. A process for preparing (110) dislocation-free monocrystalline silicon, characterized in that the process includes the following steps:
(1) clear the furnace and tidy the heat field: charge argon into the furnace, clean the sub-furnace room, clean the graphite pieces and volatile in the hearth and the hearth;
(2) load the furnace: put the graphite pieces into the furnace in turn, and make the furnace column on its place, put multi-crystal material and alloy into a quartz crucible, allow the lower hole of the sub-room jointed with the upper hole of the furnace column, clean the seed crystal collet, set up (110) seed crystal, then seal the furnace;
(3) vacuumize, charge argon: when the vacuum meets under the set value, charge argon;
(4) heat raw material: turn on the rotation outfit of the crucible, adjust its place and begin to heat;
(5) crystal seeding: the raw material is burned up completely, after the temperature of the melt in furnace is stable, bake the crystal and fuse the crystal seeding, pull the thin neck;
(6) expand shoulder: shoulder-expanding is carried out, monitor the diameter of the expanded shoulder;
(7) rotate shoulder: speeding up the speed of shoulder-expanding;
(8) equal diameter: after the shoulder rotation, stabilize the crystal growth speed;
(9) finish: turn off the power of the crucible, decrease the drawing rate manually for finishing;
(10) turn off the furnace: raise the crystal off the liquid surface, turn off the heating switch, crystal growth, crystal rotation, crucible rotation, crucible power, stopping charge of argon.

2. The process for preparing (110) dislocation-free monocrystalline silicon of claim 1, characterized in that said vacuumizing and charging argon is carried out under air pressure below 5 Pa, and the argon flow is at 50 L/min, furnace pressure indication is at 1300-1500 Pa.

3. The process for preparing (110) dislocation-free monocrystalline silicon of claim 1, characterized in that, during heat the raw material, adjusting the crucible mark at +1090˜+1100 mm, the OP value of Eurotherm is added to 20, then the OP value is added by 25 every 15 min, that is slowly adding the power till the OP value is 100, when the material is all fallen down into the quartz crucible, the crucible mark is at 1015˜1025 mm.

4. The process for preparing (110) dislocation-free monocrystalline silicon of claim 1, characterized in that, during crystal seeding, the diameter of seed should be ≧5 mm, obvious retractation and expansion are necessary, the ratio of retractation and expansion is higher than 100%, the drawing rate of crystal seeding should be ≧5 mm/min, the length of crystal seeding is 140˜300 mm.

5. The process for preparing (110) dislocation-free monocrystalline silicon of claim 1, characterized in that, said expanding shoulder is to expand shoulder then gradually reducing the growth speed of crystal seeding to 0.5˜0.7 mm/min, during expanding shoulder, the speed is controlled at 0.2˜1.5 mm/min.

6. The process for preparing (110) dislocation-free monocrystalline silicon of claim 1, characterized in that, said shoulder rotation is to improve the drawing rate to 2.2 mm/min when the diameter is 150-130 mm, the diameter of the shoulder is controlled at 150-160 mm.

7. The process for preparing (110) dislocation-free monocrystalline silicon of claim 1, characterized in that in said equal diameter step, the drawing rate of the single crystal head is 1.0-3.0 mm/min, the drawing rate of the tail should be 0.5-2.0 mm/min.

8. The process for preparing (110) dislocation-free monocrystalline silicon of claim 1, characterized in that in said finishing step, the length of single crystal is larger than the diameter of the crystal, minimum diameter at finishing is ≧10 mm.

9. A graphite heating system for producing (110) dislocation-free monocrystalline silicon, including an upper insulation column (1), a lower insulation column (2) and a hearth tray (3) arranged from the top down to form the external shell, and wherein the peripheral surface of the upper insulation column (1), lower insulation column (2) and hearth tray (3) is a flat structure, a draft tube (4) is set inside, a quartz crucible (5) filled with silicon liquid and a graphite crucible (6) covered outside, a graphite axis (7) connected at bottom of the graphite crucible (6), a heater (8) on the outside of the graphite crucible (6), characterized in that, the peripheral surface of said upper insulation column (1), lower insulation column (2) and hearth tray (3) is a stepped structure, and the thickness of the insulation layer of the upper insulation column is 20-30 mm, the thickness of the insulation layer of the lower insulation column is 60-70 mm, the thickness of the insulation layer of the hearth tray is 70-80 mm.

10. A (110) dislocation-free monocrystalline silicon, being cylinder structure, characterized in that, on the expanded shoulders of (110) dislocation-free monocrystalline silicon 2 symmetrical main crest lines (11) and 4 sub-crest lines (12) at the two sides of the 2 main crest lines (11) are formed, on the crystal cylinder surface of (110) dislocation-free monocrystalline silicon 2 symmetrical main crest lines (11) extended from the expanded shoulders are formed.
